(19) United States
(12) Patent Application Publication
(10) Pub. No.: US 2026/0005001 A1
(43) Pub. Date: Jan. 1, 2026

(54) MOVEABLE EDGE RINGS FOR PLASMA PROCESSING SYSTEMS

(71) Applicant: LAM RESEARCH CORPORATION, Fremont, CA (US)

(72) Inventors: Christopher KIMBALL, San Jose, CA (US); Darrell EHRLICH, San Jose, CA (US); Johnny PHAM, San Jose, CA (US)

(21) Appl. No.: 18/879,860

(22) PCT Filed: Sep. 15, 2022
(86) PCT No.: PCT/US2022/043617

§ 371 Date: Dec. 30, 2024

Related U.S. Application Data
(60) Provisional application No. 63/358,054, filed on Jul. 1, 2022.

(51) Int. Cl. H01J 37/32

(52) U.S. Cl. CPC H01J 37/32642

(57) ABSTRACT

An edge ring system includes a moveable top ring and a cover ring configured to be arranged above and radially outward of the moveable top ring. The cover ring includes an annular body and a stepped portion extending radially inward from the annular body. The stepped portion is configured to extend above an outer edge of the moveable top ring. An annular recess is defined in an inner radius of the cover ring below the stepped portion. The moveable top ring includes an annular body and a curved outer radius. A ring centering portion is formed in a lower surface of the annular body and configured to center the moveable top ring on a moveable support ring.

### CROSS-REFERENCE TO RELATED APPLICATIONS

This application claims the benefit of U.S. Provisional Application No. 63/358,054, filed on Jul. 1, 2022. The entire disclosure of the application referenced above is incorporated herein by reference.

### FIELD

The present disclosure relates generally to plasma processing systems and more particularly to edge ring systems with a moveable edge ring.

### BACKGROUND

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. Process gas mixtures may be supplied to the processing chamber to treat the substrate. Plasma may be used to ignite the gases to enhance chemical reactions.

A substrate is arranged on a substrate support during treatment. An edge ring has an annular body that is arranged around and adjacent to a radially outer edge of the substrate. The edge ring may be used to shape or focus the plasma onto the substrate. During operation, the substrate and an exposed surface of the edge ring is etched by the plasma. As a result, the edge ring wears and the effect of the edge ring on the plasma changes, which may adversely affect uniformity.

### SUMMARY

A cover ring for an edge ring system is configured to be arranged above and radially outward of a moveable top ring of the edge ring system. The cover ring includes an annular body and a stepped portion extending radially inward from the annular body. The stepped portion is configured to extend above an outer edge of the moveable top ring of the edge ring system. An annular recess is defined in an inner radius of the cover ring below the stepped portion. The annular recess is configured to receive the outer edge of the moveable top ring and a height of the annular recess is at least 60% of an overall height of the cover ring.

In other features, the cover ring is comprised of a non-conductive material. A height of the annular recess is at least 75% of an overall height of the cover ring. A width of the annular recess is at least 32% of a width of the annular body. The inner radius of the cover ring is curved. The inner radius has a radius of curvature between 0.070 and 0.090 inches. A height of the annular recess is at least 63% of an overall height of the cover ring. A width of the annular recess is at least 32% of a width of the annular body.

A moveable top ring for an edge ring system includes an annular body and a curved outer radius. A ring centering portion is formed in a lower surface of the annular body and configured to center the moveable top ring on a moveable support ring. The lower surface includes downwardly directed projections arranged at radially inner and outer locations of the annular body to define the ring centering portion.

In other features, the ring centering portion forms a cavity in the lower surface of the annular body and the downwardly directed projections are arranged on opposite sides of the cavity. Inner sidewalls of the ring centering portion are substantially vertical. The outer radius has a radius of curvature between 0.070 and 0.090 inches. A width of the ring centering portion is at least 75% of a width of the annular body. A depth of the ring centering portion is at least 26% of an overall height of the moveable top ring.

A bottom ring for an edge ring system is configured to support a cover ring of the edge ring system. The bottom ring includes an annular body, a first projection extending radially inward from an upper portion of a radially inner surface of the annular body, an annular recess defined in the radially inner surface of the annular body above the projection, the annular recess being configured to support the cover ring, and a second projection extending radially outward from an upper portion of a radially outer surface of the annular body.

In other features, a height of the annular recess is at least 6% of an overall height of the bottom ring.

An edge ring system includes a bottom ring, a cover ring, and a moveable top ring. The bottom ring includes an annular body, a projection extending radially inward from an upper portion of a radially inner surface of the annular body of the bottom ring, and an annular recess defined in the radially inner surface of the annular body above the projection. The cover ring is arranged above and radially inward of the bottom ring and supported on the projection within the annular recess of the bottom ring. The cover ring includes an annular body, a stepped portion extending radially inward from the annular body of the cover ring, and an annular recess defined in an inner radius of the cover ring below the stepped portion. The moveable top ring is arranged below and radially inward of the cover ring. The moveable top ring includes an annular body and a ring centering portion. A radially outer portion of the annular body of the moveable top ring extends below the cover ring into the annular recess of the cover ring and the ring centering portion is formed in a lower surface of the annular body of the moveable top ring.

In other features, inner sidewalls of the ring centering portion are substantially vertical. The moveable top ring further includes an annular recess arranged on an upper and radially outer portion of the annular body. The annular recess is defined by an outer sidewall and a step downward and the outer sidewall is substantially vertical. Downwardly directed projections are arranged at radially inner and outer locations of the lower surface to define the ring centering portion. The moveable top ring includes an outer radius that is curved. The outer radius has a radius of curvature between 0.070 and 0.090 inches.

In other features, the annular recess of the cover ring is configured to receive an outer edge of the moveable top ring and wherein a height of the annular recess of the cover ring is at least 70% of an overall height of the cover ring. The inner radius of the cover ring is curved. The inner radius has a radius of curvature between 0.070 and 0.090 inches. The edge ring system further includes an inner ring arranged below and radially inward of the moveable top ring. The inner ring has an “L”-shaped cross section defining an outer annular recess.

In other features, the outer annular recess is arranged to receive a radially inner edge of the moveable top ring. An outer diameter of the cover ring does not contact the bottom ring. An outer diameter of the moveable top ring does not contact the bottom ring. When in a lowest position, the moveable top ring does not contact any part of the inner ring, the cover ring, or the bottom ring.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a plasma processing system for substrates according to the present disclosure;

FIG. 2A is a side cross-sectional view of an example top ring, cover ring, and bottom ring according to certain embodiments of the present disclosure;

FIG. 2B is a top isometric view of the top ring of FIG. 2A;

FIG. 2C is a bottom isometric view of the top ring of FIG. 2A;

FIG. 2D is a side cross-sectional view of the entire top ring of FIG. 2A;

FIG. 2E is a side cross-sectional view of a portion of a body of the top ring of FIG. 2A;

FIG. 2F is a bottom isometric view of the cover ring of FIG. 2A;

FIG. 2G is a side cross-sectional view of the entire cover ring of FIG. 2A;

FIG. 2H is a side cross-sectional view of a portion of a body of the cover ring of FIG. 2A;

FIG. 2I is a top isometric view of the bottom ring of FIG. 2A;

FIG. 2J is a side cross-sectional view of a portion of the bottom ring of FIG. 2A;

FIG. 2K is a side cross-sectional view of the entire bottom ring of FIG. 2A;

FIG. 2L is a top isometric view of an inner ring of FIG. 2A;

FIG. 2M is a side cross-sectional view of a portion of the inner ring of FIG. 2A;

FIG. 2N is a side cross-sectional view of the entire inner ring of FIG. 2A;

FIG. 3A is a side cross-sectional view of another example top ring, cover ring, and bottom ring according to certain embodiments of the present disclosure;

FIG. 3B is a top isometric view of the top ring of FIG. 3A;

FIG. 3C is a bottom isometric view of the top ring of FIG. 3A;

FIG. 3D is a side cross-sectional view of the entire top ring of FIG. 3A;

FIG. 3E is a side cross-sectional view of a portion of a body of the top ring of FIG. 3A;

FIG. 3F is a bottom isometric view of the cover ring of FIG. 3A;

FIG. 3G is a side cross-sectional view of the entire cover ring of FIG. 3A; and

FIG. 3H is a side cross-sectional view of a portion of a body of the cover ring of FIG. 3A.

In the drawings, reference numbers may be reused to identify similar and/or identical elements.

### DETAILED DESCRIPTION

During substrate processing, a substrate is arranged on a pedestal such as an electrostatic chuck (ESC), process gases are supplied, and plasma is struck in the processing chamber. Exposed surfaces of components within the processing chamber experience wear due to exposure to the plasma.

For example, an edge ring is arranged around a radially outer edge of the substrate to shape the plasma. After processing substrates, the exposed surface of the edge ring may be worn down and sits at a different height relative to the substrate. As a result, the effect of the edge ring on the plasma changes, which alters the effect of the process on the substrate. Therefore, in some substrate processing systems, the processing chamber will need to be opened to replace the worn edge ring.

To reduce process changes due to edge ring wear without breaking vacuum, some processing chambers deploy adjustable edge rings. These processing chambers may increase the height position of the adjustable edge ring to compensate for wear or to allow tuning for different process conditions in a recipe. This approach increases the time between edge ring replacement, which reduces replacement cost and decreases the overall down time.

As the height position of the edge ring changes, capacitive coupling between the plasma, the sheath and/or capacitance delivery structures (including the edge ring) also changes. These changes in capacitive coupling can cause substrate processing non-uniformities over time. For example, changes in capacitive coupling cause changes in voltages on components such as the edge ring, which in turn affects the plasma sheath near the edge of the substrate, tilt at the edge of the substrate, etc. Capacitive coupling variation may also occur in response to other factors such as thermal expansion of the edge rings, erosion of gaps between adjacent rings and part-to-part variability.

In some instances, coatings, spacers and/or minimum gaps are used to minimize capacitance variation. However, these mechanisms may reduce the overall coupling capacitance, which lowers the RF voltage on the edge ring. For example, these mechanisms result in more consistent but larger gaps, which reduces coupling capacitance and causes the plasma sheath to bend downward. As a result, higher geometric height for the rings surrounding the base plate would ease the downward bend of the plasma sheath and promote a more vertical tilt. For example, increasing the height of components such as the edge ring, a cover ring, etc. could cause the plasma sheath to bend upward.

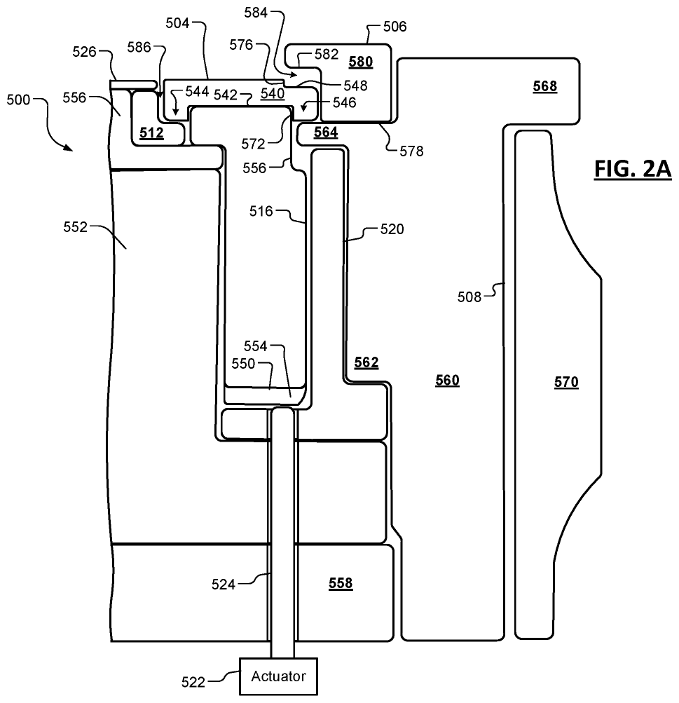

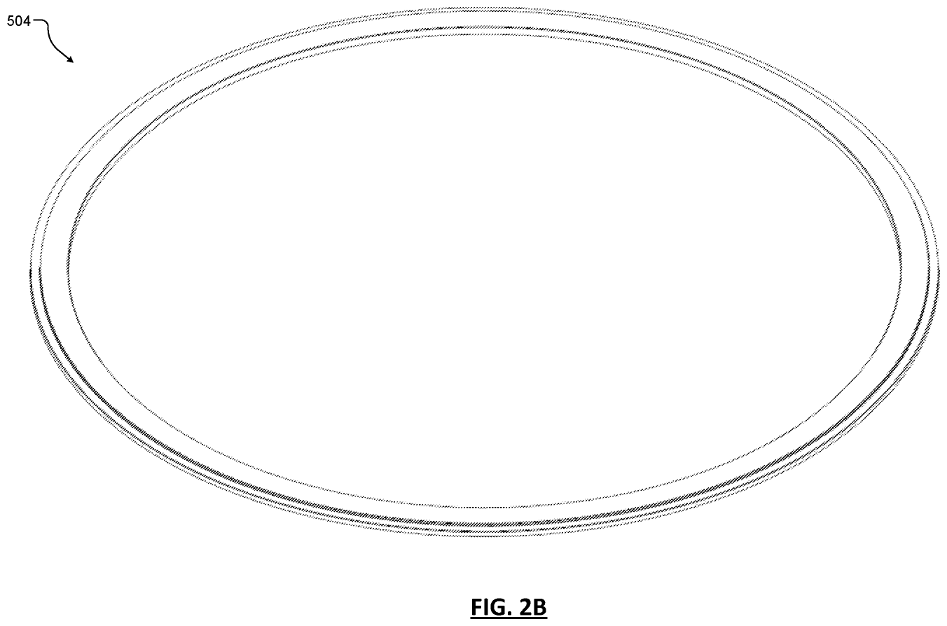

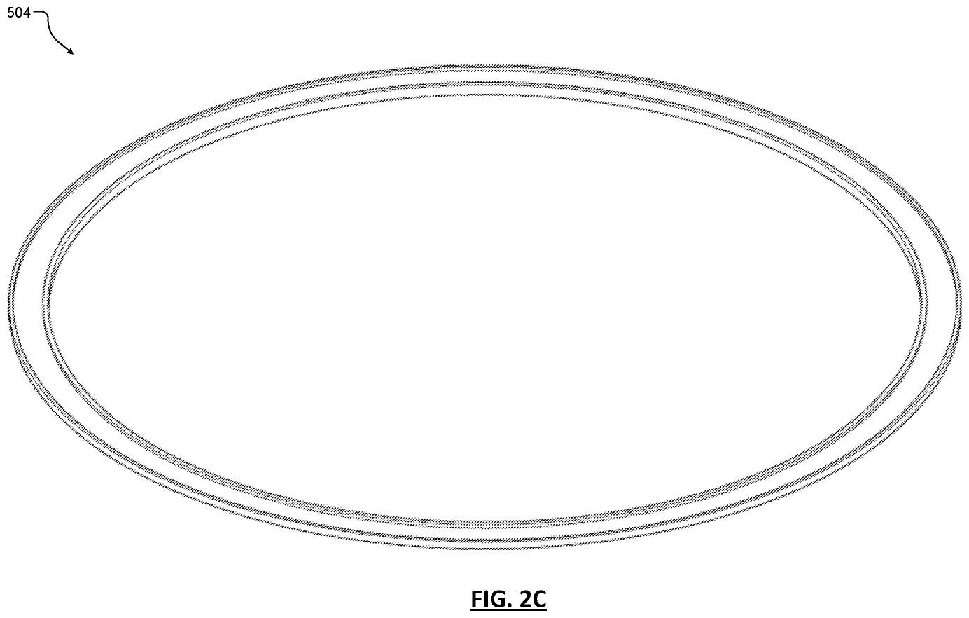

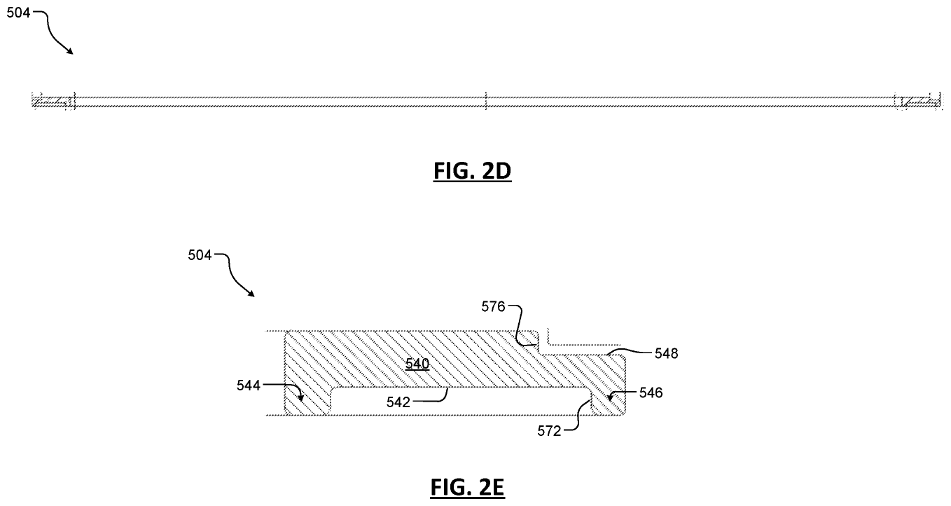

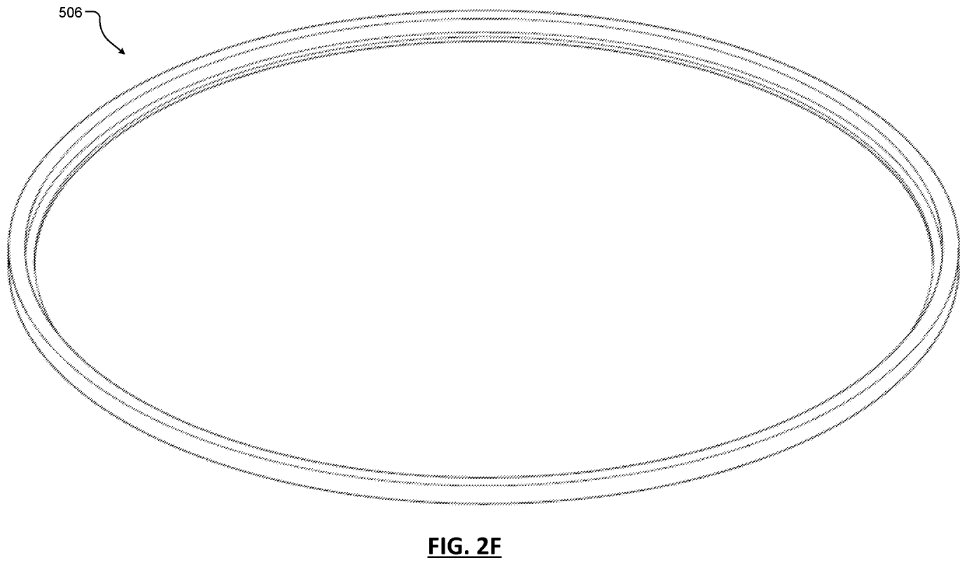

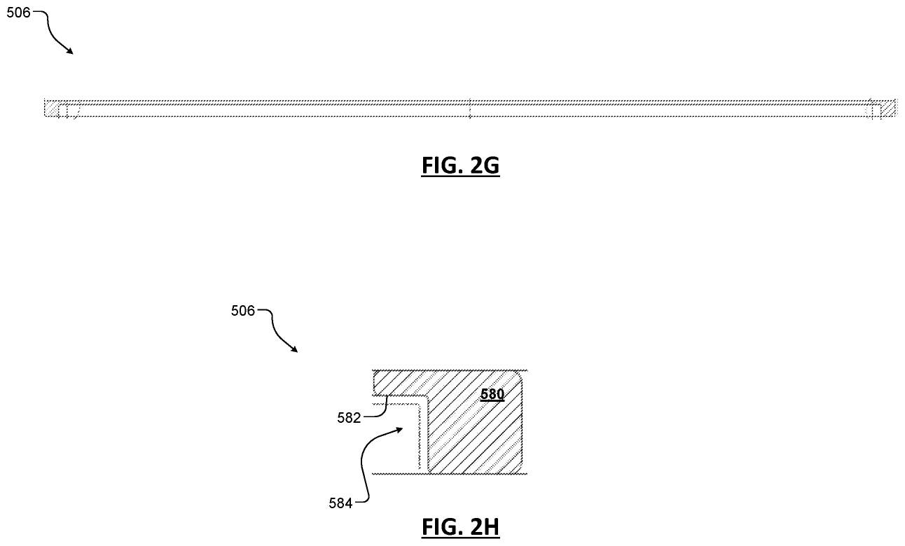

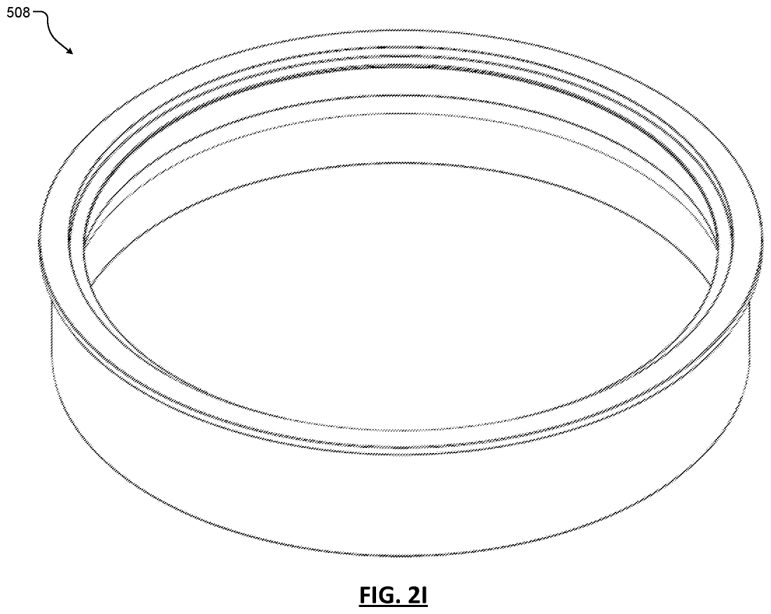

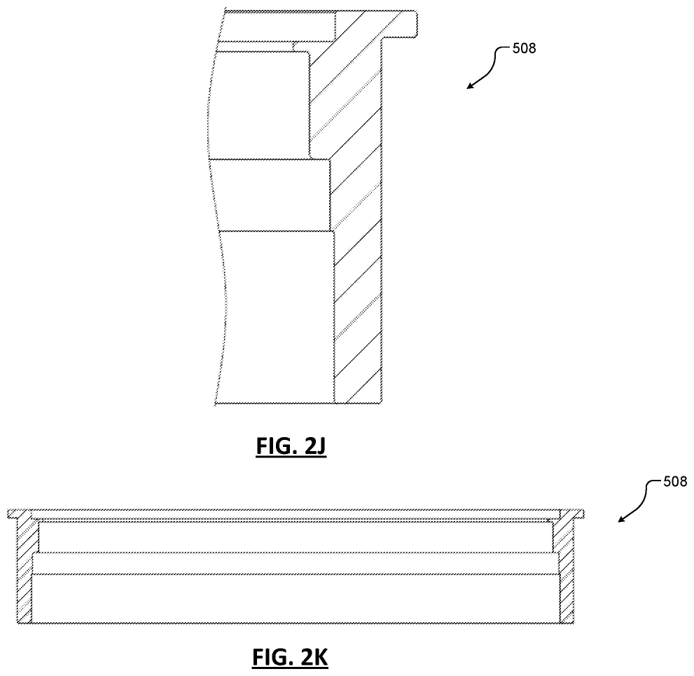

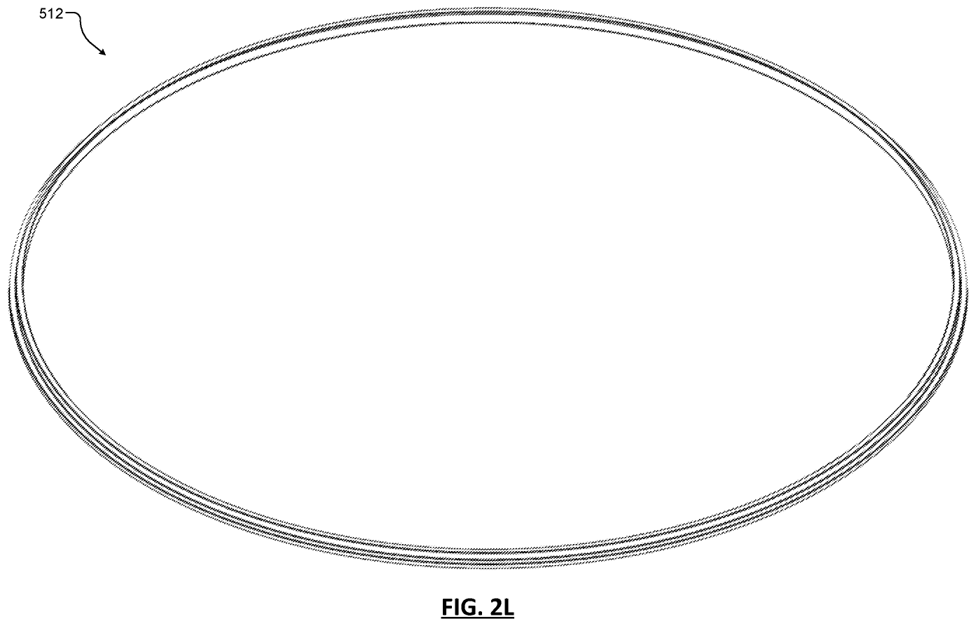

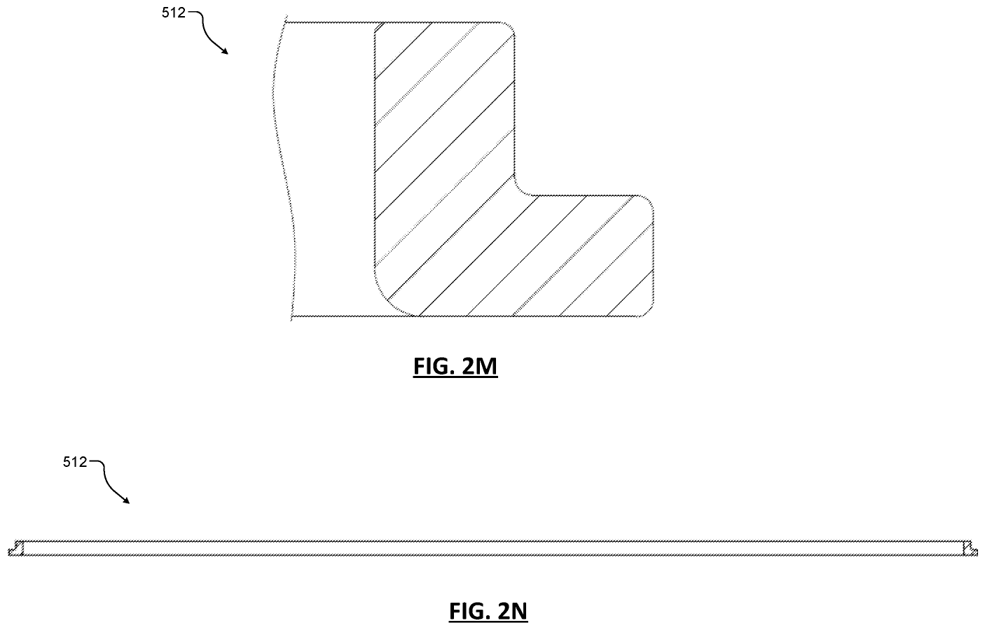

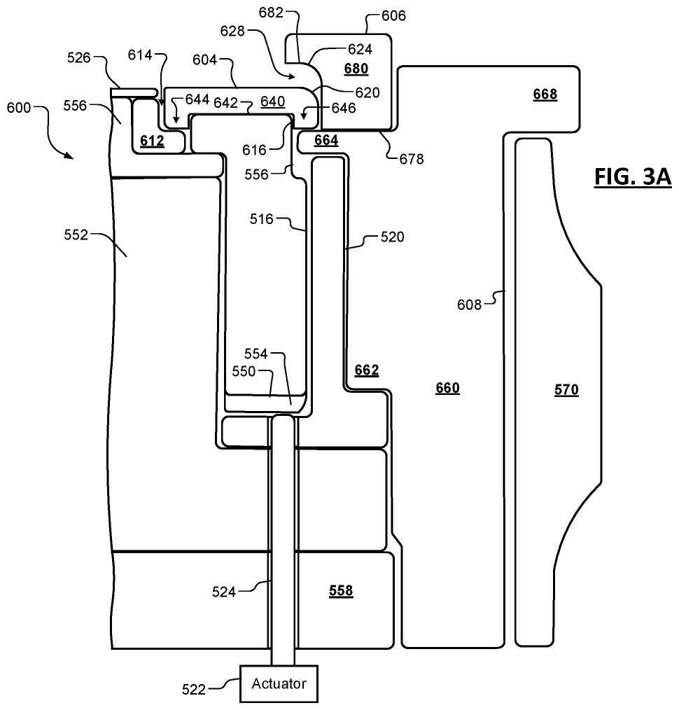

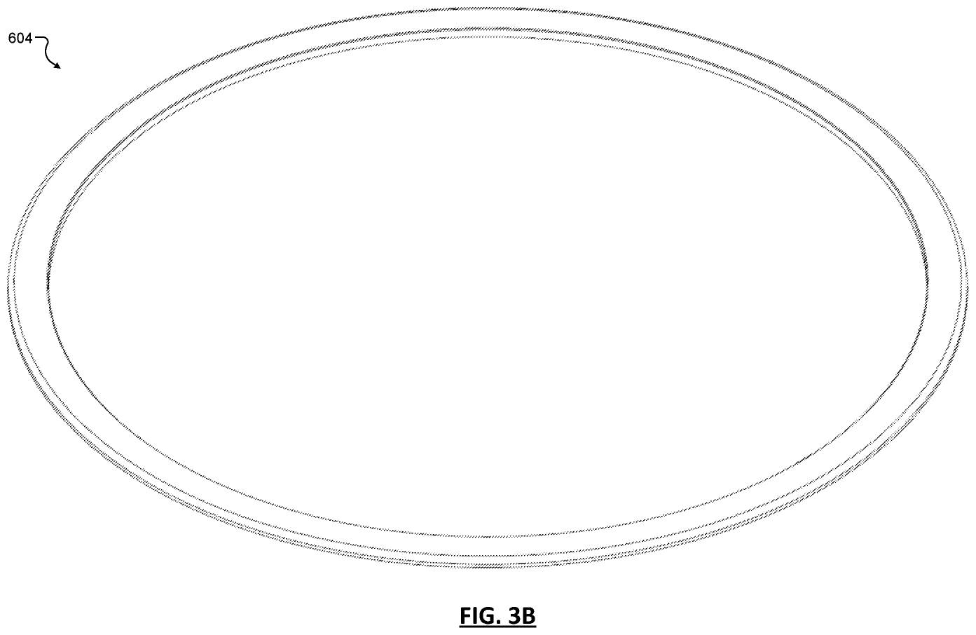

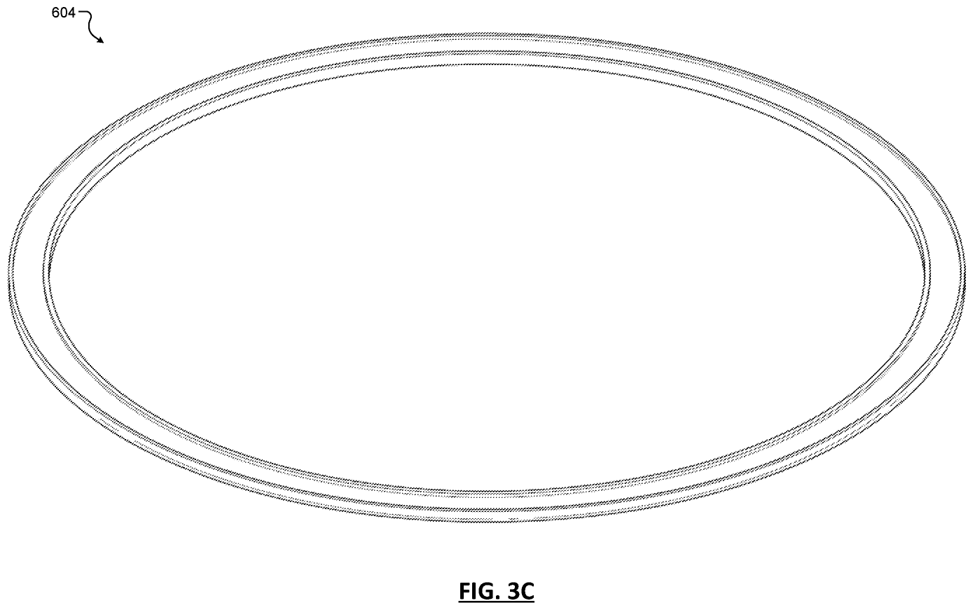

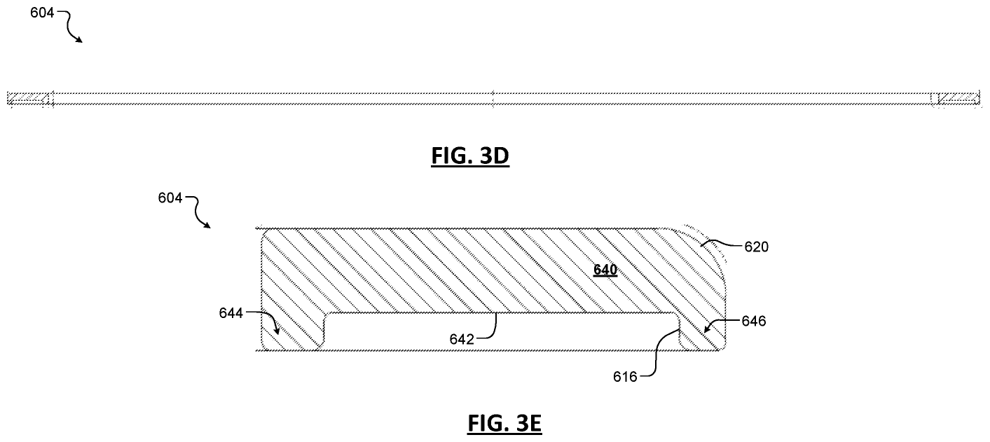

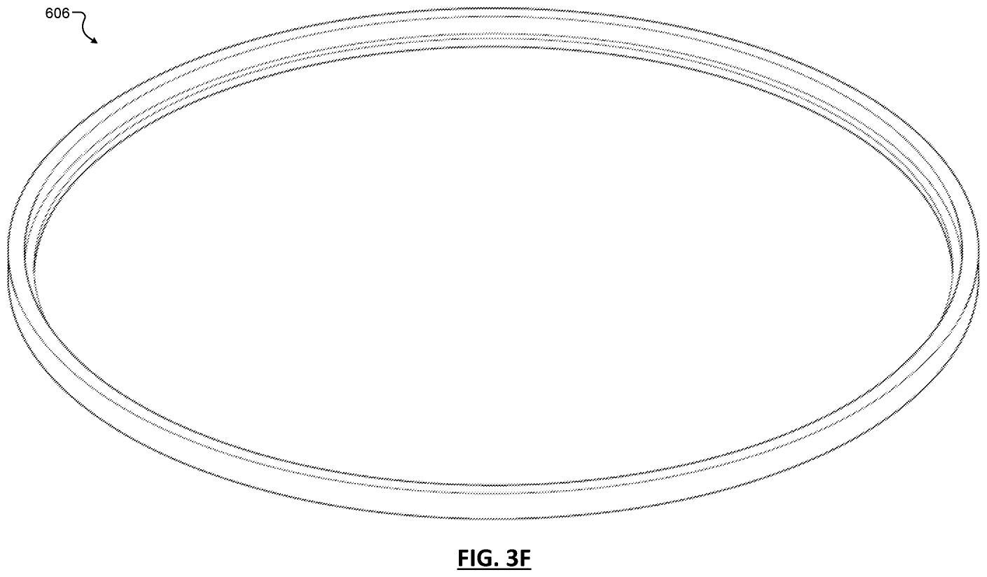

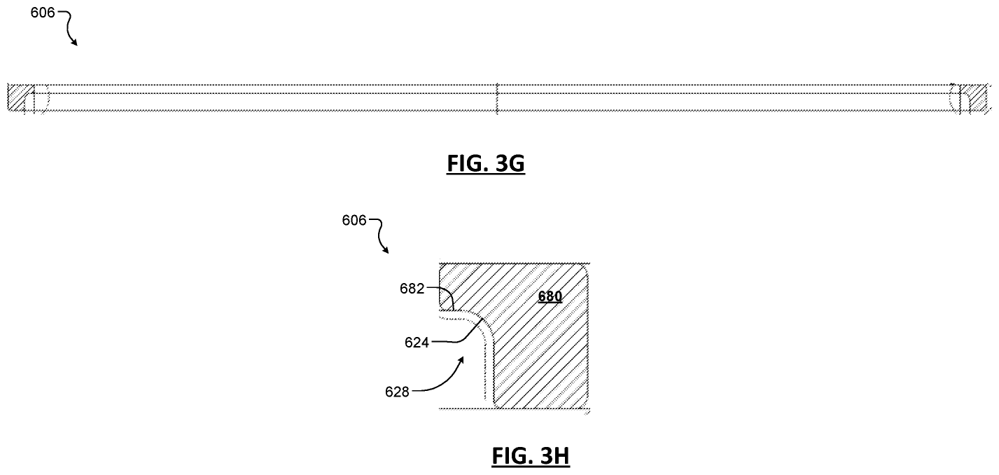

Various edge ring arrangements according to the present disclosure are configured to reduce capacitive coupling variation as the moveable top ring is worn. FIGS. 2A-2L and 3A-H illustrate novel edge ring systems/arrangements, tunable moveable top rings, cover rings, and bottom rings. As further described below, the height position of the moveable top ring relative to the top surface of the base plate, cover ring, or bottom ring can be changed by moving the moveable top ring up or down using an actuator system such as a moveable support ring and lift pins.

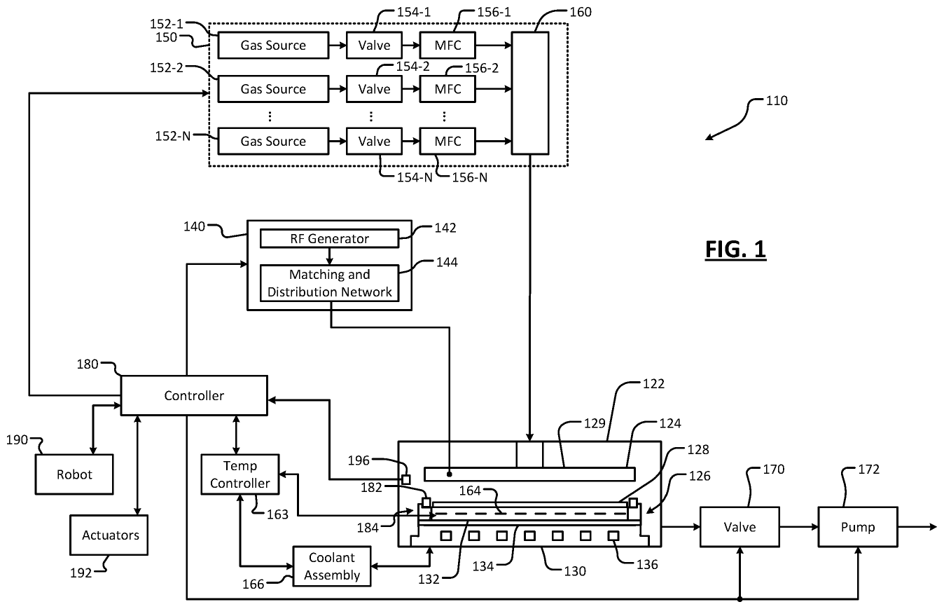

Referring now to FIG. 1, an example of a substrate processing system 110 that performs plasma processing and that includes a movable edge ring system according to certain embodiments of the present disclosure is shown. While a specific type of plasma processing chamber is shown, other plasma processing chambers can be used. The substrate processing system 110 may be used to perform etching using capacitively coupled plasma (CCP). The substrate processing system 110 includes a processing chamber 122 that encloses other components of the substrate processing system 110 and contains the RF plasma (if used). The substrate processing system 110 includes an upper electrode 124 and a substrate support 126 such as an electrostatic chuck (ESC). During operation, a substrate 128 is arranged on the substrate support 126.

For example only, the upper electrode 124 may include a gas distribution device 129 such as a showerhead that introduces and distributes process gases. The gas distribution device 129 may include a stem portion including one end connected to a top surface of the processing chamber. An annular body is generally cylindrical and extends radially outwardly from an opposite end of the stem portion at a location that is spaced from the top surface of the processing chamber. A substrate-facing surface or faceplate of the annular body of the showerhead includes a plurality of holes through which precursor, reactants, etch gases, inert gases, carrier gases, other process gases or purge gas flows. Alternately, the upper electrode 124 may include a conducting plate and the process gases may be introduced in another manner.

The substrate support 126 includes a baseplate 130 that acts as a lower electrode. The baseplate 130 supports a heating plate 132, which may correspond to a ceramic multi-zone heating plate. A bonding and/or a thermal resistance layer 134 may be arranged between the heating plate 132 and the baseplate 130. The baseplate 130 may include one or more channels 136 for flowing coolant through the baseplate 130.

An RF generating system 140 generates and outputs an RF voltage to one of the upper electrode 124 and the lower electrode (e.g., the baseplate 130 of the substrate support 126). The other one of the upper electrode 124 and the baseplate 130 may be DC grounded, AC grounded or floating. For example only, the RF generating system 140 may include an RF generator 142 that generates RF plasma power that is fed by a matching and distribution network 144 to the upper electrode 124 or the baseplate 130. In other examples, the plasma may be generated inductively or remotely.

A gas delivery system 150 includes one or more gas sources 152-1, 152-2, . . . , and 152-N (collectively gas sources 152), where N is an integer greater than zero. The gas sources 152 are connected by valves 154-1, 154-2, . . . , and 154-N (collectively valves 154) and MFCs 156-1, 156-2, . . . , and 156-N (collectively MFCs 156) to a manifold 160. Secondary valves may be used between the MFCs 156 and the manifold 160. While a single gas delivery system 150 is shown, two or more gas delivery systems can be used.

A temperature controller 163 may be connected to a plurality of thermal control elements (TCEs) 164 arranged in the heating plate 132. The temperature controller 163 may be used to control the plurality of TCEs 164 to control a temperature of the substrate support 126 and the substrate 128. The temperature controller 163 may communicate with a coolant assembly 166 to control coolant flow through the channels 136. For example, the coolant assembly 166 may include a coolant pump, a reservoir and/or one or more temperature sensors. The temperature controller 163 operates the coolant assembly 166 to selectively flow the coolant through the channels 136 to cool the substrate support 126.

A valve 170 and pump 172 may be used to evacuate reactants from the processing chamber 122. A system controller 180 may include one or more controllers that are used to control components of the substrate processing system 110. In some examples, a moveable edge ring 182 is arranged radially outside of the substrate 128 during plasma processing and is exposed to plasma. In other examples, a moveable edge ring is located below a stationary edge ring that is exposed to plasma. An edge ring height position adjustment system 184 may be used to adjust a height position of a top surface of the moveable edge ring 182 relative to the substrate 128 (or to alter the RF voltage of the stationary edge ring) as will be described further below. In some examples, the moveable edge ring 182 can also be raised, removed by a robot end effector and replaced with another edge ring without breaking vacuum.

In certain embodiments, the system controller 180 controls a robot 190 to deliver substrates and/or edge rings to the processing chamber as will be described further below. The system controller 180 also controls one or more actuators 192 that move lift pins to adjust a height position or tilt of the edge rings as further described below. The system controller 180 may also receive outputs from one or more sensors 196 that are used to sense a height of the edge rings. Non-limiting examples of sensors include optical sensors, physical sensors, piezo sensors, ultrasonic sensors, etc.

Referring now to FIG. 2A, an example of an edge ring system 500 includes, among other components, a moveable top ring 504, a cover ring 506, a bottom ring 508, and an inner ring 512. In an embodiment, the moveable top ring 504 is comprised of silicon carbide and the cover ring 506, the bottom ring 508, and the inner ring 512 are comprised of quartz.

FIG. 2B is a top isometric view of the moveable top ring 504. FIG. 2C is a bottom isometric view of the moveable top ring 504. FIG. 2D is a cross-sectional view of the entire moveable top ring 504. FIG. 2E is a cross-sectional view of a portion of a body of the moveable top ring 504. FIG. 2F is a bottom isometric view of the cover ring 506. FIG. 2G is a cross-sectional view of the entire cover ring 506. FIG. 2H is a cross-sectional view of a portion of a body of the cover ring 506. FIG. 2I is a top isometric view of the bottom ring 508. FIG. 2J is a side cross-sectional view of a portion of the bottom ring 508. FIG. 2K is a side cross-sectional view of the entire bottom ring. FIG. 2L is a top isometric view of an inner ring 512. FIG. 2M is a side cross-sectional view of a portion of the inner ring 512. FIG. 2N is a side cross-sectional view of the entire inner ring.

The edge ring system 500 also has a moveable support ring 516 and a shield ring 520. The moveable top ring 504 is directly exposed to plasma during processing. When installed, the moveable top ring 504 rests on the moveable support ring 516. An actuator 522 biases a lift pin 524 into a lower surface of the moveable support ring 516 to adjust a position of the moveable top ring 504 relative to a substrate 526.

The moveable top ring 504 includes an annular body 540. In some examples, the moveable top ring 504 includes a ring centering portion 542 to center the moveable top ring 504 on the moveable support ring 516. In some examples, the ring centering portion 542 includes a cavity formed on a lower surface thereof. In some examples, the cavity has a width sufficient to receive an upper portion of the moveable support ring 516. Downwardly directed projections 544 and 546 of the moveable top ring 504 are arranged at radially inner and outer locations of the annular body 540 on opposite sides of the cavity. In some examples, an annular recess 548 is arranged on an upper and radially outer portion of the annular body 540.

In some examples, a lower portion of the moveable support ring 516 includes a ring centering portion 550 to center the moveable support ring 516 relative to a baseplate 552. In some examples, a heating layer 556 (e.g., a ceramic layer) is arranged above the baseplate 552. A bonding layer (not shown) may be arranged between the heating layer 556 and the baseplate 552. The baseplate 552 may be arranged on a supporting plate 558.

As can be appreciated, all of the edge ring systems described herein may include the ring centering portion 550. In some examples, the ring centering portion 550 includes a cavity 554 having an inner surface that includes a portion that is sloped linearly or non-linearly (e.g., curved) to bias the moveable support ring 516 into position as it is seated on the lift pin 524. In some examples, the surface of the cavity includes opposing surfaces that provide a centering effect. In some examples, the surface of the cavity has a “V”-shape, a cone shape, a combination of straight and curved shapes or other types of surfaces that provide a centering effect.

The shield ring 520 includes an annular body that partially surrounds the moveable support ring 516. The bottom ring 508 is arranged radially outside of the moveable top ring 504, the moveable support ring 516 and the shield ring 520. The shield ring 520 prevents electrical coupling between the moveable support ring 516 (which is powered) and the bottom ring 508. In this manner, voltage supplied to the moveable top ring 504 via the moveable support ring 516 is maximized.

The bottom ring 508 includes an annular body 560, a first projection 562 extending radially inwardly from a middle portion of a radially inner surface of the bottom ring 508. A projection 564 extends radially inwardly from an upper portion of a radially inner surface of the bottom ring 508. In some examples, at least a portion of the projection 564 is arranged below the downwardly projection 546 of the moveable top ring 504. A projection 568 projects radially outwardly from the upper surface of the bottom ring 508. An outer ring 570 is arranged radially outside of the bottom ring 508 and may be made of a conductive material.

Referring to FIG. 2E, inner sidewalls 572 of the ring centering portion 542 are substantially vertical. For example, between about 0.015 and 0.025 inches (0.38 and 0.6 m millimeters) of the inner sidewalls 572 are vertical. The vertical orientation of the sidewalls 572 facilitates centering of the moveable top ring 504 relative to the support ring 516. Similarly, the annular recess 548 is defined by an outer sidewall 576 that is substantially vertical. The annular recess 548 defines a step downward that facilitates arrangement of the moveable top ring 504 below the cover ring 506.

In an embodiment, an overall outer diameter of the moveable top ring 504 is between about 12.8 and 13.2 inches (about 325 and 335 millimeters). A width of the annular body 540 is between about 0.5 and 0.6 inches (about 13 and 16 millimeters). For example, the width of the annular body 540 is configured to minimize the gap between the outer diameter of the moveable top ring 504 and the cover ring 506. Further, the width of the annular body 540 is configured to maximize a voltage potential of the moveable top ring 504 for a given amount of power supplied to the moveable top ring 504 from the moveable support ring 516. For example, as a width (e.g., an overall volume) of the moveable top ring 504 increases, the amount of power supplied would also need to be increased. As one example, the width of the of the annular body is no greater than about 0.75 inches (about 19 millimeters).

A width of the annular recess 548 is between about 0.12 and 0.16 inches (about 3 and 4 millimeters). For example, the width of the annular recess 548 is at least 20% of a width of the annular body 540. A depth of the annular recess is between about 0.035 and 0.045 inches (about 0.8 and 1.2 millimeters). For example, the depth of the annular recess 548 is at least 25% of an overall height of the moveable top ring 504. An overall height of the moveable top ring 504 is between about 0.125 and 0.140 inches (about 3.1 and 3.6 millimeters).

A width of the ring centering portion 542 is between about 0.4 and 0.5 inches (about 10 and 13 millimeters). For example, the width of the ring centering portion 542 is at least 75% of a width of the annular body 540. In an example, a width of a contact area (e.g., an overlap) between the ring centering portion 542 and the upper surface of the moveable support ring 516 is at least 0.2 inches (10 millimeters). As one example, a gap between the inner sidewalls 572 of the ring centering portion 542 and the moveable support ring is at least about 0.003 inches (about 0.076 millimeters). In some examples, the gap may be greater (e.g., between about 0.010 and 0.013 inches (about 0.25 and 0.33 millimeters) to accommodate thermal expansion of the moveable top ring 504 during operation. In some examples, the upper surface of the moveable support ring 516 occupies at least 97% of the ring centering portion 542.

A height or depth of the ring centering portion 542 (e.g., the cavity) is between about 0.040 and 0.050 inches (about 1.0 and 1.3 millimeters), which corresponds to the height of the downwardly directed projections 544 and 546. For example, the depth of the ring centering portion 542 is at least 28% of an overall height of the moveable top ring 504. The depth of the ring centering portion 542 is configured to provide sufficient vertical contact area between the sidewalls of the ring centering portion 542 and the upper end of the moveable support ring 516 to prevent misalignment in a lateral direction when the moveable top ring 504 is installed on the moveable support ring 516 and when the moveable support ring 516 is used to raise and lower the moveable top ring 504, etc.

The cover ring 506 is located above the bottom ring 508 and has an upper surface that is directly exposed to plasma. In some examples, an annular recess 578 is defined in an upper surface of the bottom ring 508. In some examples, the cover ring 506 rests on the annular recess 578. The cover ring 506 includes an annular body 580 and a stepped portion 582. When installed, the stepped portion 582 extends radially inward above and overlaps the annular recess 548 of the moveable top ring 504. The annular recess 548 increases the gap between the upper surface of the moveable top ring 504 and the lower surface of the stepped portion 582 to reduce likelihood of arcing between the moveable top ring 504 and the cover ring 506 relative to moveable top rings without the annular recess 548. In other words, without the annular recess 548, the upper surface of the moveable top ring 504 below the stepped portion 582 is nearer to the lower surface of the stepped portion 582, increasing the likelihood of arcing.

Further, the stepped portion 582 extends over a gap between the outer diameter of the top movable ring and the inner diameter of the cover ring 506 to disrupt line of sight from the plasma environment to structures below the moveable top ring 504 and the cover ring 506 (e.g., the bottom ring 508, the moveable support ring 516, etc.).

As shown in FIG. 2A, in some assembly configurations, the cover ring 506 has a greater height relative to the moveable top ring 504 and extends above the bottom ring 508. Accordingly, a height or depth of an annular recess 584 defined below the stepped portion 582 is greater than a height of the moveable top ring 504. In other words, a height of the annular recess 584 from the bottom of the cover ring 506 to a bottom surface of the stepped portion 582 is greater than the height of the moveable top ring 504. As shown, the cover ring 506 extends from a bottom of the recess 578 to a height above an upper surface of the bottom ring 508. In other words, the height of the cover ring 506 is greater than a height of the recess 578. The cover ring 506 also extends to a height above the upper surface of the moveable top ring 504.

Dimensions such as the overall height of the moveable top ring 504, the depth of the annular recess 548, and the height of the annular recess 584 are configured to define a desired gap (i.e., in a vertical direction) between the upper surface of the annular recess 548 and the lower surface of the stepped portion 582. For example, the gap between the surface of the annular recess 548 and the lower surface of the stepped portion 582 is between about 0.08 and 0.12 inches (about 2.0 and 3.0 millimeters) when the moveable support ring 516 is in a lowest position.

For example, in some embodiments, the moveable top ring 504 is powered to control process uniformity, which may cause greater erosion of the cover ring 506 (e.g., erosion of an inner diameter of the cover ring 506). For example, a voltage on the upper surface of the moveable top ring 504 below the stepped portion 582 increases a voltage on the surface of the cover ring 506, which increases the energy of ions bombarding the cover ring 506.

Accordingly, since a height at the inner diameter of the cover ring 506 (and a thickness of the stepped portion 582) determines a usable life of the cover ring 506, the thickness or height of the cover ring 506 is at least about 0.245 inches (about 6.2 millimeters) in order to extend the usable life of the cover ring 506. Further, in this embodiment, a width of the cover ring 506 is selected to provide a gap between an outer diameter of the cover ring 506 and the bottom ring 508. In other words, when assembled for operation, the outer diameter of the cover ring 506 does not contact the bottom ring 508. Further, an outer diameter of the moveable top ring 504 is not directly adjacent to and/or define a gap with any inner diameter of the bottom ring 508. The gaps prevent binding between surfaces (e.g., vertical services) of adjacent moving and stationary ring structures. In this context, the term stationary refers to rings that are not generally moved after installation without breaking vacuum and the term moveable means that a position of the rings can be adjusted after installation without breaking vacuum by an actuator as described herein.

In an embodiment, an overall outer diameter of the cover ring 506 is between about 13.25 and 13.5 inches (about 336 and 343 millimeters). A width of the annular body 580 of the cover ring 506 is between about 0.34 and 0.39 inches (about 8.6 and 9.9 millimeters). An overall height of the cover ring 506 is between about 0.245 and 0.260 inches (about 6.2 and 6.6 millimeters). A height of the annular recess 584 is between about 0.185 and 0.195 inches (about 4.6 and 5.0 millimeters). For example, the height of the annular recess 584 is at least 60% of an overall height of the cover ring 506. In an embodiment, the height of the annular recess 584 is at least 75% of an overall height of the cover ring 506. A width of the annular recess 584 is between about 0.10 and 0.15 inches (about 2.5 and 3.8 millimeters). For example, the width of the annular recess 584 is at least 32% of an overall width of the annular body 580. Accordingly, the width of the annular recess 584 is configured to accommodate an entirely of the portion of the moveable top ring 504 corresponding to the annular recess 548. Further, the outer diameter of the moveable top ring 504 does not contact an inner diameter of the cover ring 506 while the moveable top ring 504 is in a lowest position, while raising and lowering the moveable top ring 504, etc.

Accordingly, the annular recess 578 of the bottom ring 508 is configured to accommodate the cover ring 506 having a height or thickness of at least about 0.20 inches (about 5.0 millimeters). Further, when assembled for operation, an outer diameter of the moveable top ring 504 does not contact an inner diameter of the cover ring 506, and a bottom surface of the moveable top ring 504 does not contact (i.e., is not supported on) an upper surface of the projection 564 of the bottom ring 508. In this manner, the moveable top ring 504, the cover ring 506, and the bottom ring 508 can be manufactured with tighter tolerances since the outer diameter of the moveable top ring 504 is only proximate to an inner diameter of the cover ring 506. Typically, manufacturing tolerances must be selected such that sufficient gaps between components are ensured to prevent binding or contact between components, ensure that components will fit together properly, etc. Accordingly, looser manufacturing tolerances may result in larger gaps. The configuration described above allows tighter manufacturing tolerances, which refers to smaller maximum gaps between components. In other words, any possibility of contact between the outer diameter of the moveable top ring 504 and an inner diameter of the cover ring 506 or any portion of the bottom ring 508 is eliminated while still minimizing the widths of the gaps.

In an embodiment, an overall outer diameter of the bottom ring 508 is between about 14.60 and 14.80 inches (about 370 and 376 millimeters). An overall height of the bottom ring 508 is between about 2.85 and 2.95 inches (about 72 and 75 millimeters). A width of the annular recess 578 is between about 0.25 and 0.35 inches (about 6.3 and 8.9 millimeters). A height of the annular recess 578 is between about 0.20 and 0.30 inches (about 5.0 and 7.6 millimeters). As described above, the annular recess 578 of the bottom ring 508 is configured to accommodate the cover ring 506 having a height or thickness of at least about 0.20 inches (about 5.0 millimeters). Further, the width of the annular recess 578 is configured to accommodate and support an entire width of the lower surface of the cover ring. In other words, the cover ring 506 is arranged between the outer diameter of the moveable top ring and an inner diameter of the bottom ring 508 that form a part of the annular recess 578. Further, the projection 564 defining a lower surface of the annular recess 578 extends above and protects the shield ring 520, while the projection 568 extends above and protects the outer ring 570.

In embodiments, when the moveable support ring 516 is at a lowest position, the moveable top ring 504 rests on top of the moveable support ring 516 and only contacts the moveable support ring 516 (as shown in FIG. 2A). In other words, in the lowest position, the moveable top ring 504 does not contact any part of the inner ring 512, the cover ring 506, or the bottom ring 508. Accordingly, there is no risk of binding between the moveable top ring 504 and stationary components such as the cover ring 506, the bottom ring 508, the inner ring 512, etc. during movement of the moveable top ring 504. Further, since the moveable top ring 504 is powered, lack of contact between the moveable top ring 504 and other components reduces the risk of electrical communication between the moveable top ring 504 and the other components.

In some embodiments, the inner ring 512 has a generally “L”-shaped cross section defining an outer annular recess 586. The outer annular recess 586 is configured to receive the downwardly directed projection 544 of the moveable top ring 504. An overall outer diameter of the inner ring 512 is between about 11.95 and 12.05 inches (about 303 and 306 millimeters). An inner diameter of the inner ring 512 is between about 11.55 and 11.75 inches (about 293 and 299 millimeters). An overall height of the inner ring 512 is between about 0.175 and 0.195 inches (about 4.4 and 5.0 millimeters). A height of the annular recess 586 is between about 0.10 and 0.12 inches (about 2.54 and 3.048 millimeters). A width of the annular recess 586 is between about 0.080 and 0.095 inches (about 2.0 and 2.4 millimeters).

Referring now to FIG. 3A, another example of an edge ring system 600 includes, among other components, a moveable top ring 604, a cover ring 606, a bottom ring 608, and an inner ring 612. In an embodiment, the moveable top ring 604 is comprised of silicon carbide and the cover ring 606, the bottom ring 608, and the inner ring 612 are comprised of quartz.

FIG. 3B is a top isometric view of the moveable top ring 604. FIG. 3C is a bottom isometric view of the moveable top ring 604. FIG. 3D is a side cross-sectional view of the entire moveable top ring 604. FIG. 3E is a side cross-sectional view of a portion of a body 680 of the moveable top ring 604. FIG. 3F is a bottom isometric view of the cover ring 606. FIG. 3G is a side cross-sectional view of the entire cover ring 606. FIG. 3H is a side cross-sectional view of a portion of the body 680 of the cover ring 606.

In edge ring system 600, the bottom ring 608 and an inner ring 612 are substantially the same as the bottom ring 508 and the inner ring 512 described above. For example, the bottom ring 608 includes an annular body 660. A first projection 662 extends radially inwardly from a middle portion of a radially inner surface of the bottom ring 608. A projection 664 extends radially inwardly from an upper portion of a radially inner surface of the bottom ring 608. A projection 668 projects radially outwardly from the upper surface of the bottom ring 608.

In an embodiment, the inner ring 612 has a generally “L”-shaped cross section defining an outer annular recess 614. The outer annular recess 614 is configured to receive a downwardly directed projection 644 of the moveable top ring 604. In an embodiment, an overall outer diameter of the bottom ring 608 is between about 14.60 and 14.80 inches (about 370 and 376 millimeters). An overall height of the bottom ring 608 is between about 2.85 and 2.95 inches (about 72 and 75 millimeters). A width of an annular recess 678 is between about 0.25 and 0.35 inches (about 6.3 and 8.9 millimeters). A height of the annular recess 678 is between about 0.20 and 0.30 inches (about 5.0 and 7.6 millimeters). For example, the height of the annular recess 678 is at least 6% of an overall height of the bottom ring 608.

A ring centering portion 642 of the moveable top ring 604 is defined between the downwardly directed projection 644 and a downwardly directed projection 646. In some embodiments, inner sidewalls 616 of the ring centering portion 642 are substantially vertical. The vertical orientation of the sidewalls 616 facilitates centering of the moveable top ring 604 relative to the support ring 516. As shown in FIG. 3E, an outer radius 620 of the moveable top ring 604 is curved. The curved outer radius 620 reduces electric field concentrations associated with sharper corners, thereby reducing likelihood of arcing between surfaces of the moveable top ring 604 and the cover ring 606. Arcing increases erosion of surfaces exposed to plasma and decreases a lifetime of components such as the moveable top ring 604 and the cover ring 606.

In an embodiment, an overall outer diameter of the moveable top ring 604 is between about 12.8 and 13.2 inches (about 325 and 335 millimeters). A width of an annular body 640 of the moveable top ring 604 is between about 0.5 and 0.6 inches (about 13 and 16 millimeters). An overall height of the moveable top ring 604 is between about 0.135 and 0.150 inches (about 3.4 and 3.8 millimeters). A width of the ring centering portion 642 is between about 0.4 and 0.5 inches (about 10 and 13 millimeters). For example, the width of the ring centering portion 642 is at least 75% of the width of the annular body 640. A height or depth of the ring centering portion 642 is between about 0.040 and 0.050 inches (about 1.0 and 1.3 millimeters). For example, the depth of the ring centering portion 642 is at least 26% of an overall height of the moveable top ring 604.

A radius of curvature of the outer radius 620 is between about 0.070 and 0.090 inches (about 1.7 and 2.3 millimeters). The radius of curvature is configured to reduced electric field concentrations associated with sharper corners, such as corners in right angled or chamfered transitions from an upper surface to sidewalls of the moveable top ring 604. Accordingly, the greater the radius of curvature, the greater the reduction of electric field concentrations. However, if the radius of curvature is too large, the vertical gap/interface between the outer diameter of the moveable top ring 604 and the inner diameter of the cover ting 606 would be significantly reduced or eliminated, allowing direct line-of-sight to structures below the moveable top ring 604 and the cover ring 606. Accordingly, the radius of curvature described above is configured so that a vertical portion of the outer diameter of the moveable top ring 604 is between about 0.040 and 0.075 inches (about 1.0 and 1.9 millimeters).

In FIG. 3A, an inner radius 624 of the cover ring 606 is curved in a manner similar to the outer radius 620 to reduce electric field concentrations. Further, the cover ring 606 has a greater height relative to the moveable top ring 604 and extends above the bottom ring 608. Accordingly, a height or depth of an annular recess 628 defined below a stepped portion 682 is greater than a height of the moveable top ring 604. In other words, a height of the annular recess 628 from the bottom of the cover ring 606 to a bottom surface of the stepped portion 682 is greater than the height of the moveable top ring 604. As shown, the cover ring 606 extends from a bottom of the recess 678 and a bottom of the moveable top ring 604 to a height above an upper surface of the bottom ring 608. In other words, the height of the cover ring 606 is greater than a height of the recess 678 to extend a usable life of the cover ring 606. The cover ring 606 also extends to a height above the upper surface of the moveable top ring 604.

In an embodiment, an overall outer diameter of the cover ring 606 is between about 13.25 and 13.5 inches (about 336 and 343 millimeters). A width of the annular body 680 of the cover ring 606 is between about 0.33 and 0.37 inches (about 8.3 and 9.4 millimeters). An overall height of the cover ring 606 is between about 0.345 and 0.360 inches (about 8.7 and 9.2 millimeters). A height of the annular recess 628 is between about 0.230 and 0.250 inches (about 5.8 and 6.4 millimeters). For example, the height of the annular recess 628 is at least 63% of an overall height of the cover ring 606. A width of the annular recess 628 is between about 0.10 and 0.15 inches (about 2.5 and 3.8 millimeters). For example, the width of the annular recess 628 is at least 32% of a width of the annular body 680. A radius of curvature of the inner radius 624 is between about 0.070 and 0.090 inches (about 1.7 and 2.3 millimeters).

In the preceding embodiments, some of the edge rings are made of a conductive material or a conductive or non-conductive material with a conductive coating. As used herein, conductive refers to materials or coatings with a resistivity of less than or equal to 10⁴ Ωcm. For example, doped silicon has a resistivity of 0.05 Ωcm, silicon carbide has a resistivity of 1-300 Ωcm and metals such as aluminum and copper have a resistivity of ≈10⁻⁷ Ωcm. In some examples, the edge rings of the present disclosure are made of non-conductive material or a conductive or non-conductive material with a non-conductive coating. As used herein, nonconductive refers to materials/coatings with a resistivity of greater than 10⁴ Ωcm.

The conductive rings can be made of one or more base materials, one or more plating layers, and/or one or more coatings. Non-limiting examples of base materials include silicon, silicon carbide, titanium, graphite, quartz, and/or ceramic. Non-limiting examples of plating layers include aluminum plating. Non-limiting examples of coatings include perfluoroalkoxy (PFA), atomic layer deposition (ALD) aluminum oxide (Al₂O₃), ALD yttrium oxide or yttria (Y₂O₃), and/or anodized coatings. For example, the conductive materials may include anodized titanium, silicon with a PFA coating, doped silicon, silicon with aluminum plating and an anodized coating, silicon with ALD aluminum oxide, silicon with an ALD yttria coating, silicon carbide, graphite with a PFA coating, graphite with aluminum plating and an anodized coating, graphite with an ALD aluminum oxide coating, graphite with an ALD yttria coating, or other suitable materials. Non-limiting examples of non-conductive materials include quartz and ceramic. In the preceding embodiments, one or more of the rings may be formed by one or more structures in radial, axial or other directions.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.” As used herein, the term “about” means +/−10% of a given value and/or +/−5% of a given percentage.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A cover ring for an edge ring system, the cover ring configured to be arranged above and radially outward of a moveable top ring of the edge ring system, the cover ring comprising:
an annular body;
a stepped portion extending radially inward from the annular body, wherein the stepped portion is configured to extend above an outer edge of the moveable top ring of the edge ring system; and
an annular recess defined in an inner radius of the cover ring below the stepped portion, wherein the annular recess is configured to receive the outer edge of the moveable top ring, and wherein a height of the annular recess is at least 60% of an overall height of the cover ring.

2. The cover ring of claim 1, wherein the cover ring is comprised of a non-conductive material.

3. The cover ring of claim 1, wherein a height of the annular recess is at least 75% of an overall height of the cover ring.

4. The cover ring of claim 1, wherein a width of the annular recess is at least 32% of a width of the annular body.

5. The cover ring of claim 1, wherein the inner radius of the cover ring is curved.

6. The cover ring of claim 5, wherein the inner radius has a radius of curvature between 0.070 and 0.090 inches.

7. The cover ring of claim 5, wherein a height of the annular recess is at least 63% of an overall height of the cover ring.

8. The cover ring of claim 5, wherein a width of the annular recess is at least 32% of a width of the annular body.

9. A moveable top ring for an edge ring system, the moveable top ring comprising:
an annular body;
an outer radius of the annular body, wherein the outer radius is curved; and
a ring centering portion formed in a lower surface of the annular body and configured to center the moveable top ring on a moveable support ring, wherein the lower surface includes downwardly directed projections arranged at radially inner and outer locations of the annular body to define the ring centering portion.

10. The moveable top ring of claim 9, wherein the ring centering portion forms a cavity in the lower surface of the annular body, and wherein the downwardly directed projections are arranged on opposite sides of the cavity.

11. The moveable top ring of claim 9, wherein inner sidewalls of the ring centering portion are substantially vertical.

12. The moveable top ring of claim 9, wherein the outer radius has a radius of curvature between 0.070 and 0.090 inches.

13. The moveable top ring of claim 9, wherein a width of the ring centering portion is at least 75% of a width of the annular body.

14. The moveable top ring of claim 9, wherein a depth of the ring centering portion is at least 26% of an overall height of the moveable top ring.

15. A bottom ring for an edge ring system, the bottom ring being configured to support a cover ring of the edge ring system, the bottom ring comprising
an annular body;
a first projection extending radially inward from an upper portion of a radially inner surface of the annular body;
an annular recess defined in the radially inner surface of the annular body above the projection, the annular recess being configured to support the cover ring; and
a second projection extending radially outward from an upper portion of a radially outer surface of the annular body.

16. The bottom ring of claim 15, wherein a height of the annular recess is at least 6% of an overall height of the bottom ring.

17. An edge ring system, comprising:
a bottom ring, the bottom ring comprising (i) an annular body, (ii) a projection extending radially inward from an upper portion of a radially inner surface of the annular body of the bottom ring, and (iii) an annular recess defined in the radially inner surface of the annular body above the projection;
a cover ring arranged above and radially inward of the bottom ring and supported on the projection within the annular recess of the bottom ring, the cover ring comprising (i) an annular body, (ii) a stepped portion extending radially inward from the annular body of the cover ring, and (iii) an annular recess defined in an inner radius of the cover ring below the stepped portion; and
a moveable top ring arranged below and radially inward of the cover ring, the moveable top ring comprising (i) an annular body, wherein a radially outer portion of the annular body of the moveable top ring extends below the cover ring into the annular recess of the cover ring, and (iii) a ring centering portion formed in a lower surface of the annular body of the moveable top ring.

18. The moveable top ring of claim 17, wherein inner sidewalls of the ring centering portion are substantially vertical.

19. The edge ring system of claim 18, the moveable top ring further comprising:
an annular recess arranged on an upper and radially outer portion of the annular body, wherein the annular recess is defined by an outer sidewall and a step downward, and wherein the outer sidewall is substantially vertical; and
downwardly directed projections arranged at radially inner and outer locations of the lower surface to define the ring centering portion.

20. The edge ring system of claim 17, the moveable top ring comprising an outer radius that is curved.

21. The edge ring system of claim 20, wherein the outer radius has a radius of curvature between 0.070 and 0.090 inches.

22. The edge ring system of claim 17, wherein the annular recess of the cover ring is configured to receive an outer edge of the moveable top ring, and wherein a height of the annular recess of the cover ring is at least 70% of an overall height of the cover ring.

23. The edge ring system of claim 17, wherein the inner radius of the cover ring is curved.

24. The edge ring system of claim 23, wherein the inner radius has a radius of curvature between 0.070 and 0.090 inches.

25. The edge ring system of claim 17, further comprising an inner ring arranged below and radially inward of the moveable top ring, wherein the inner ring has an “L”-shaped cross section defining an outer annular recess.

26. The edge ring system of claim 25, wherein the outer annular recess is arranged to receive a radially inner edge of the moveable top ring.

27. The edge ring system of claim 26, wherein an outer diameter of the cover ring does not contact the bottom ring.

28. The edge ring system of claim 26, wherein an outer diameter of the moveable top ring does not contact the bottom ring.

29. The edge ring system of claim 26, wherein, when in a lowest position, the moveable top ring does not contact any part of the inner ring, the cover ring, or the bottom ring.
